(19) United States
(12) Patent Application Publication
(10) Pub. No.: US 2026/0056315 A1
(43) Pub. Date: Feb. 26, 2026

(54) MOVABLE INSPECTION DEVICE

(71) Applicant: SAMSUNG ELECTRONICS CO., LTD., Suwon-si (KR)

(72) Inventors: Jong Ho PARK, Suwon-si (KR); Ji Ha JUNG, Suwon-si (KR); Dong Won CHAE, Suwon-si (KR); Hyo-Chun PARK, Suwon-si (KR); Chae Kyu JANG, Suwon-si (KR)

(73) Assignee: SAMSUNG ELECTRONICS CO., LTD., Suwon-si (KR)

(21) Appl. No.: 19/304,097

(22) Filed: Aug. 19, 2025

(30) Foreign Application Priority Data
Aug. 23, 2024 (KR) 10-2024-0113514
Feb. 13, 2025 (KR) 10-2025-0018743

(51) Int. Cl. G01S 17/06; B65G 47/90; H01L 21/67; H01L 21/687

(52) U.S. Cl. CPC G01S 17/06; B65G 47/90; H01L 21/67259; H01L 21/68707

(57) ABSTRACT

An inspection device includes a housing having an entrance through which a robot enters and retracts in a first direction, and a substrate mounting rail on which a substrate is mounted; a cover configured to open and close the entrance; a first plate module including a first plate mounted on the substrate mounting rail and a displacement sensor installed on the first plate; a controller provided inside the housing and configured to analyze data measured by the displacement sensor; a display device provided inside, on a surface of, or outside the housing and configured to display information received from the controller and the displacement sensor; and a battery provided inside the housing and configured to supply power to the controller and the display device.

### CROSS-REFERENCE TO RELATED APPLICATION

This application claims priority under 35 U.S.C. § 119 to Korean Patent Application No. 10-2024-0113514 filed on Aug. 23, 2024, and Korean Patent Application No. 10-2025-0018743 filed on Feb. 13, 2025 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a movable inspection device.

### 2. Description of the Related Art

In semiconductor manufacturing processes, wafers are processed in a cleanroom to improve yield and quality. However, as device integration increases, circuits become more miniaturized, and wafers increase in size, maintaining the entire cleanroom in a clean state has become technically and financially challenging. To address this issue, recent efforts have been focused on managing cleanliness only in the space surrounding wafers. Specifically, wafers can be stored inside a sealed storage pod called a carrier (e.g., a front-opening unified pod (FOUP)). For wafer transfer between processing equipment and the carrier, a device called an equipment front end module (EFEM) is used. The transported carrier (or FOUP) is placed on the EFEM of each processing equipment, and the EFEM can open the cover of the carrier (or FOUP) to expose the wafers. The end effector of the atmospheric transfer robot in the EFEM retrieves (or gets) one of the multiple wafers loaded inside the carrier (or FOUP) and transfers it to the processing chamber inside the processing equipment. Once processing is completed, the processed wafer is placed (or put) back into the carrier (or FOUP). However, when the end effector enters the carrier (or FOUP) to perform a get or put operation, it may enter at an inclined angle. If the end effector enters the carrier (or FOUP) in an inclined state and performs a get or put operation, the wafer may be scratched or damaged by the end effector.

### SUMMARY

An inspection device according to the present disclosure includes a plate with a sensor inside a housing, allowing determination of whether an end effector that enters the inspection device and performs a get or put operation is inclined or whether the end effector accurately performs the get or put operation at a designated position.

By determining the position and inclination of the end effector during operation, abnormal movements of the end effector can be detected, preventing wafer damage caused by such movements in advance.

Additionally, the inspection device according to the present disclosure includes a displacement sensor, a controller, and a battery inside the housing, offering ease of installation and maintenance.

A problem to be solved by the present disclosure is to provide an inspection device with enhanced reliability.

Another problem to be solved by the present disclosure is to provide a movable inspection device.

The objectives of the present disclosure are not limited to those mentioned above, and other objectives not explicitly stated will be clearly understood by those skilled in the art based on the following description.

According to an aspect of the present disclosure, there is provided an inspection device comprising: a housing having an entrance through which a robot enters and retracts in a first direction, and a substrate mounting rail on which a substrate is mounted; a cover configured to open and close the entrance; a first plate module including a first plate mounted on the substrate mounting rail and a displacement sensor installed on the first plate; a controller provided inside the housing and configured to analyze data measured by the displacement sensor; a display device provided inside, on a surface of, or outside the housing and configured to display information received from the controller and the displacement sensor; and a battery provided inside the housing and configured to supply power to the controller and the display device, wherein when the displacement sensor and the robot overlap in a second direction intersecting the first direction, the displacement sensor measures a position of the robot in the second direction.

According to another aspect of the present disclosure, there is provided an inspection device comprising: a housing including an entrance through which a robot enters and retracts in a first direction and a substrate mounting rail on which a substrate is mounted; a cover configured to open and close the entrance; a first plate module including a first plate mounted on the substrate mounting rail and a plurality of displacement sensors installed on the first plate; a controller provided inside the housing and configured to analyze data measured by the plurality of displacement sensors; a display device provided inside, on a surface of, or outside the housing and configured to display information received from the controller and the plurality of displacement sensors; and a battery provided inside the housing and configured to supply power to the controller and the display device, wherein when the plurality of displacement sensors and the robot overlap in a second direction intersecting the first direction, each of the plurality of displacement sensors measures a position of the robot in the second direction.

According to the other aspect of the present disclosure, there is provided an inspection device comprising: a housing including an entrance through which a robot enters and retracts in a first direction and a substrate mounting rail on which a substrate is mounted; a cover configured to open and close the entrance; a first plate module including a first plate mounted on the substrate mounting rail, a displacement sensor installed on the first plate, a leveling sensor configured to measure whether the first plate is level, a preload structure configured to fix the first plate to the substrate mounting rail, and a latch having one end fixed to the first plate to be rotatable; a second plate module including a second plate provided inside the housing and a reflector installed on the second plate and overlapping with the displacement sensor in a second direction intersecting the first direction; a third plate module including a third plate provided inside the housing, a controller installed on the third plate and configured to analyze data measured by the displacement sensor, and a battery installed on the third plate and configured to supply power to the controller; and a display device provided inside, on a surface of, or outside the housing and configured to display information received from the controller and the displacement sensor, wherein the preload structure includes a preload portion formed by a part of the first plate extending in the second direction and including an elastic body, and a support portion formed by the preload portion extending in a third direction intersecting the first and second directions, and when the displacement sensor and the robot overlap in the second direction, the displacement sensor measures a position of the robot in the second direction, and the second plate module, the robot, and the first plate module are sequentially arranged along the second direction.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing exemplary embodiments thereof in detail with reference to the attached drawings, in which:

FIG. 1 is a perspective view illustrating inspection devices and a substrate processing apparatus according to some embodiments of the present disclosure.

FIG. 2 is a plan view illustrating the inspection devices and the substrate processing apparatus according to some embodiments of the present disclosure.

FIG. 3 is a perspective view illustrating an inspection device according to some embodiments of the present disclosure.

FIG. 4 is a rear perspective view illustrating the inspection device according to some embodiments of the present disclosure.

FIG. 5 is a perspective view illustrating a state in which a substrate is mounted on the inspection device according to some embodiments of the present disclosure.

FIG. 6 is an exploded perspective view illustrating an inspection device according to some embodiments of the present disclosure.

FIG. 7 is a plan view of a first plate module illustrated in FIG. 6.

FIG. 8 is a rear view of a second plate module illustrated in FIG. 6.

FIG. 9 is a plan view of a third plate module illustrated in FIG. 6.

FIG. 10 is a cross-sectional view illustrating how the first plate module illustrated in FIG. 3 is fixed to the housing.

FIG. 11 is a cross-sectional view taken along line A-A′ of FIG. 10.

FIG. 12 is a perspective view illustrating a first inspection process of the inspection device according to some embodiments of the present disclosure.

FIG. 13 is a perspective view illustrating a second inspection process of the inspection device according to some embodiments of the present disclosure.

FIG. 14 is a perspective view illustrating a third inspection process of the inspection device according to some embodiments of the present disclosure.

### DETAILED DESCRIPTION

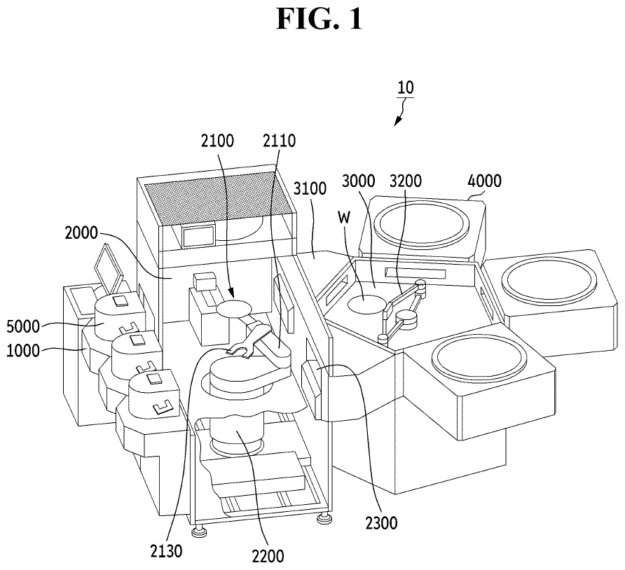

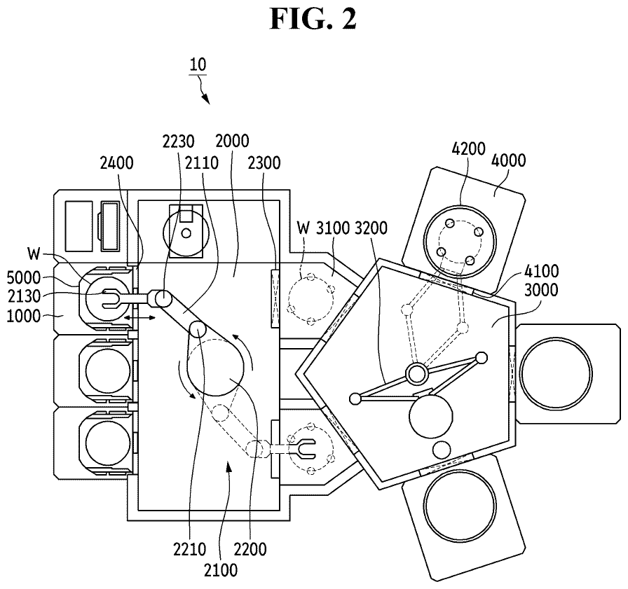

FIG. 1 is a perspective view illustrating inspection devices and a substrate processing apparatus according to some embodiments of the present disclosure. FIG. 2 is a plan view illustrating the inspection devices and the substrate processing apparatus according to some embodiments of the present disclosure.

Referring to FIGS. 1 and 2, a substrate processing apparatus 10 may perform various processes on substrates. The substrate processing apparatus 10 may include load ports 1000, an equipment front end module (EFEM) 2000, a stage 3000, processing chambers 4000, and carriers 5000, but the present disclosure is not limited thereto. In some embodiments, the substrate processing apparatus 10 may further include a controller (not illustrated) or an external server (not illustrated).

Specifically, the substrate processing apparatus 10 may include processing chambers 4000 where processes are performed on substrates W, a stage 3000 supporting the processing chambers 4000, an EFEM 2000 coupled to the front end of the stage 3000 and provided with an end effector 2130 that retrieves (or gets) or places (or puts) the substrates W inside the stage 3000, load ports 1000 coupled to the EFEM 2000, and carriers 5000 in which the substrates W are loaded and which are detachably mounted to the load ports 1000. In some embodiments, the substrate W may be a wafer.

The load ports 1000 may be coupled to the front end of the EFEM 2000 and may support the carriers 5000. A plurality of load ports 1000 may be provided, and each of the load ports 1000 may have a carrier 5000 mounted on its upper surface.

The EFEM 2000 may transfer the substrates W between the carriers 5000 mounted on the load ports 1000 and buffering chambers 3100 of the stage 3000.

The EFEM 2000 may be provided with an atmospheric transfer robot 2100 for transferring the substrates W and a transfer robot driving unit 2200 for driving the atmospheric transfer robot 2100.

The atmospheric transfer robot 2100 may retrieve unprocessed substrates from inside the carriers 5000 and load them into the buffering chambers 3100. The atmospheric transfer robot 2100 may unload processed substrates from the processing chambers 4000 and place them back into the carriers 5000. The atmospheric transfer robot 2100 may include a rotary arm 2110 and an end effector 2130 provided at the end of the rotary arm 2110 to transfer the substrates W.

The transfer robot driving unit 2200 may drive the atmospheric transfer robot 2100 such that the end effector 2130 may sequentially retrieve or place the substrates W according to the teaching values set at the time of equipment installation. The transfer robot driving unit 2200 may include a plurality of spindles 2210 and 2230 for rotating the rotary arm 2110 and the end effector 2130.

As illustrated in FIG. 2, depending on the rotation direction of the spindles 2210 and 2230, the end effector 2130 may be folded or unfolded from the rotary arm 2110 and be inserted into the carriers 5000 through carrier entrances 2400 or into the buffering chambers 3100 through buffering chamber entrances 2300.

The end effector 2130 may have the substrates W loaded on its upper surface. The end effector 2130 may be formed in various shapes, and the substrates W may be loaded on the upper surface of the end effector 2130.

The stage 3000 may support a plurality of processing chambers 4000 and may be provided with the buffering chambers 3100 connected to the EFEM 2000 and a transfer robot 3200. The stage 3000 may have a polygonal shape and may be provided with a plurality of processing chambers 4000 and a pair of buffering chambers 3100 arranged on the respective sides of the polygonal shape.

Unprocessed substrates and processed substrates, transferred by the end effector 2130, may be respectively loaded into the pair of buffering chambers 3100. The transfer robot 3200 may load unprocessed substrates from the buffering chambers 3100 into the processing chambers 4000 or unload processed substrates from the processing chambers 4000 into the buffering chambers 3100.

The processing chambers 4000 may perform treatment processes on the substrates W. The processing chambers 4000 may each include a susceptor 4200 on which a substrate W is placed. The processing chambers 4000 may be configured to perform various substrate processing operations. For example, the processing chambers 4000 may be ashing chambers for removing photoresist, chemical vapor deposition (CVD) chambers configured to deposit insulating films, or etching chambers configured to form apertures or openings in the insulating films to create interconnect structures. Alternatively, the processing chambers 4000 may be physical vapor deposition (PVD) chambers configured to deposit barrier films or metal films.

The buffering chambers 3100, the stage 3000, and the processing chambers 4000 may be provided with sensor units (not illustrated) capable of detecting their current operating status. The sensor units may include a plurality of pressure sensors, temperature sensors, or concentration sensors for detecting parameters such as the pressure, temperature, plasma gas concentration, and number of processed substrates inside the buffering chambers 3100, the stage 3000, and the processing chambers 4000. In addition, various other sensors for detecting the current operating status of the buffering chambers 3100, stage 3000, and processing chambers 4000 may be provided.

The processing chambers 4000 and the stage 3000 may operate in a vacuum state, whereas the load ports 1000 and the EFEM 2000 may operate in an atmospheric pressure state. The buffering chambers 3100 of the stage 3000 may alternate between vacuum and atmospheric pressure conditions.

The carriers 5000 accommodate a plurality of substrates W therein and may be detachably coupled between different substrate processing apparatuses, allowing the substrates W to sequentially undergo different processes. The carriers 5000 may be mounted on the upper surfaces of the respective load ports 1000, as illustrated in FIG. 1. Each of the carriers 5000 may function as an inspection device in this disclosure. The inspection devices according to some embodiments of the present disclosure may refer to the carriers 5000.

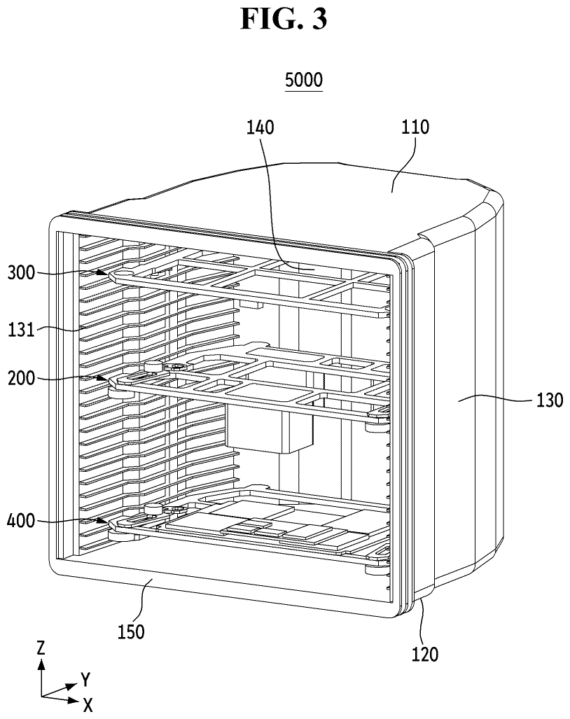

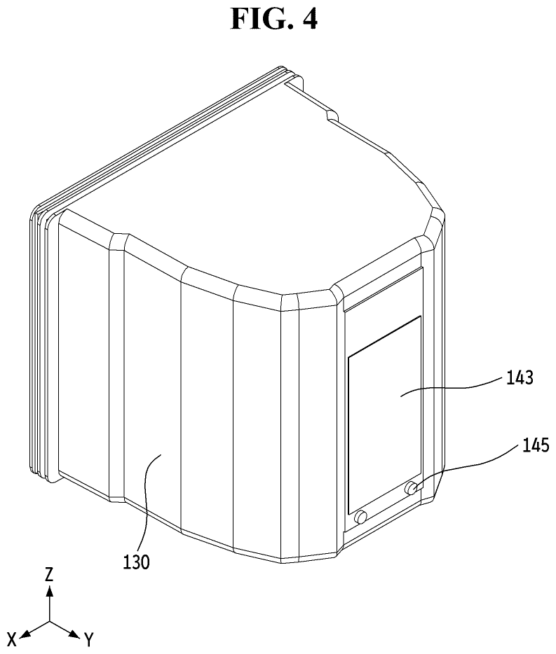

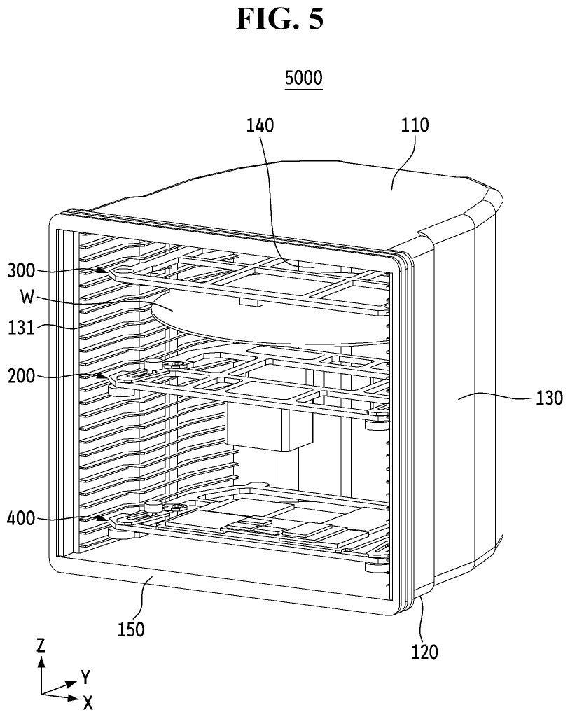

FIG. 3 is a perspective view illustrating an inspection device according to some embodiments of the present disclosure. FIG. 4 is a rear perspective view illustrating the inspection device according to some embodiments of the present disclosure. FIG. 5 is a perspective view illustrating a state in which a substrate is mounted on the inspection device according to some embodiments of the present disclosure.

Referring to FIGS. 3 to 5, a carrier 5000 may include a housing 100, a first plate module 200, a second plate module 300, and a third plate module 400. In some embodiments, the carrier 5000 may further include a cover (not illustrated).

The housing 100 may have a hexahedral shape with one open side. The housing 100 may include an upper surface 110, a lower surface 120, side surfaces 130, a rear surface 140, and an entrance 150.

The entrance 150 of the housing 100 may be an edge of the open side. The entrance 150 allows one side of the housing 100 to remain open, enabling a substrate W to enter and exit the housing 100. The entrance 150 may be arranged to correspond to a carrier entrance 2400 of the EFEM 2000. In some embodiments, the carrier 5000 may further include a cover (not illustrated) configured to open and close the entrance 150.

The housing 100 may include an upper surface 110 and a lower surface 120 that face a substrate W mounted on substrate mounting rails 131. The upper surface 110 and the lower surface 120 of the housing 100 may be connected to the entrance 150. The upper surface 110 and the lower surface 120 may face each other. The upper surface 110 and the lower surface 120 may be parallel to each other.

As the upper surface 110 and the lower surface 120 of the housing 100 extend away from the edge connected to the entrance 150, their width in a first direction X may decrease. For example, the length of the edge where the upper surface 110 or the lower surface 120 meets the entrance 150 may be greater than the length of the edge where the upper surface 110 or the lower surface 120 meets the rear surface 140.

The side surfaces 130 of the housing 100 may be connected to the upper surface 110 and the lower surface 120. The side surfaces 130 may extend in a third direction Z to connect the upper surface 110 and the lower surface 120. The side surfaces 130 of the housing 100 may include the substrate mounting rails 131 that are spaced at regular intervals along the third direction Z for holding the substrate W.

The rear surface 140 of the housing 100 may be connected to the upper surface 110, the lower surface 120, and the side surfaces 130. The rear surface 140 may be provided with a display device 143 for displaying measurement results and a charging connector 145 for charging an internal battery.

The display device 143 may display the status of a controller or sensors inside the carrier 5000, as well as data information. The display device 143 is illustrated as being installed on the rear surface 140 of the housing 100, but is not limited thereto. The display device 143 may be installed inside the housing 100 or in another location.

The charging connector 145 may be provided inside the carrier 5000 and may charge a battery that powers the internal components of the carrier 5000.

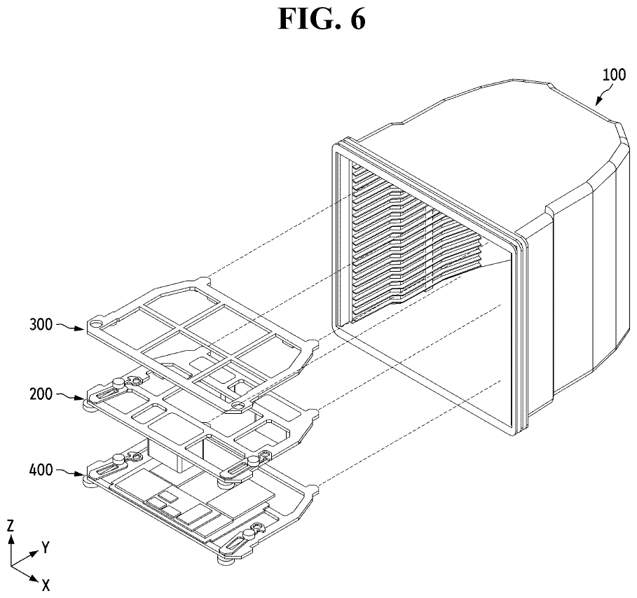

The first, second, and third plate modules 200, 300, and 400 will hereinafter be described in detail with reference to FIGS. 6 through 9.

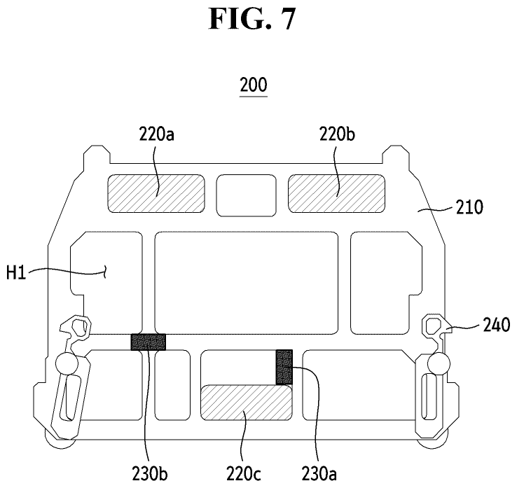

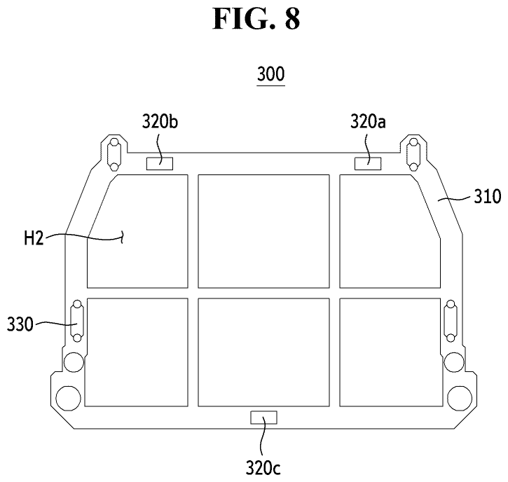

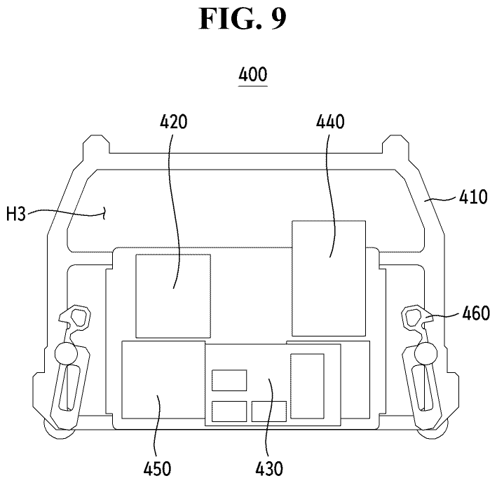

FIG. 6 is an exploded perspective view illustrating an inspection device according to some embodiments of the present disclosure. FIG. 7 is a plan view of a first plate module illustrated in FIG. 6. FIG. 8 is a rear view of a second plate module illustrated in FIG. 6. FIG. 9 is a plan view of a third plate module illustrated in FIG. 6.

Referring to FIGS. 6 and 7, a first plate module 200 may include a first plate 210, one or more displacement sensors 220, horizontal sensors 230a and 230b, and first fixing pins 240.

A carrier 5000 may include a first plate 210 parallel to an upper surface 110 and a lower surface 120 of a housing 510. The first plate 210 may be positioned between the lower surface 120 of the housing 510 and a substrate W.

In some embodiments, the first plate 210 may include first through-holes H1, which are holes passing through the first plate 210. The location, size, and number of first through-holes H1 may vary and are not limited to those illustrated. The formation of the first through-holes H1 may reduce the overall weight of the first plate module 200. By reducing the overall weight of the first plate module 200, it is possible to comply with the weight limitations for carriers specified in a system that automatically transports FOUPs in a “fab.”

The displacement sensors 220 may be installed on the first plate 210. In some embodiments, the displacement sensors 220 may be installed on the lower side of the first plate 210. When the displacement sensors 220 are installed on the lower side of the first plate 210, parts of the displacement sensors 220 may overlap the first through-holes H1, but the present disclosure is not limited thereto. The displacement sensors 220 may also be installed on the upper side of the first plate 210.

The end effector 2130 may move according to preset data. The inspection device according to some embodiments of the present disclosure may use the displacement sensors 220 to inspect whether the end effector 2130 moves according to the preset data.

The displacement sensors 220 may be provided on the first plate 210 to detect the position of the end effector 2130 entering or retracting from the carrier 5000.

For example, the displacement sensors 220 may be laser displacement sensors. The displacement sensors 220 may be integrated-type sensors that combine a light-emitting unit and a light-receiving unit. When light emitted from the light-emitting units of the displacement sensors 220 is reflected from a measurement target and enters the light-receiving units, the displacement sensors 220 may detect positional or angular changes of the reflected light to determine positional changes of the measurement target.

One or more displacement sensors 220 may be provided. For example, one to three displacement sensors 220 may be provided. A plurality of displacement sensors 220a, 220b, and 220c may each collect position data of the end effector 2130.

For example, the displacement sensors 220 may detect whether the end effector 2130 moves horizontally in a predetermined position. For example, the displacement sensors 220 may determine whether the end effector 2130 moves at an inclined angle relative to the predetermined position.

Information obtained by the displacement sensors 220 may include at least one of whether the end effector 2130 is present, whether the end effector 2130 is inclined, or the degree of inclination of the end effector 2130.

For example, the “presence” of the end effector 2130 may be determined as follows. If data collected by the displacement sensors 220 deviates from a first specific value and remains constant, it may be determined that the end effector 2130 is not present at a measurement position. If the data collected by the displacement sensors 220 deviates from the first specific value but is not constant, it may be determined that the end effector 2130 is present at the measurement position but not located in a preset position. If the data collected by the displacement sensors 220 has a first specific value, it may be determined that the end effector 2130 is present at the measurement position.

For example, the “inclination” of the end effector 2130 may be determined as follows. If the data collected by the displacement sensors 220 deviates from a second specific value, it may be determined that the end effector 2130 is inclined beyond the preset position. If the data collected by the displacement sensors 220 has the second specific value, it may be determined that the end effector 2130 is positioned in the preset position.

For example, the “degree of inclination” of the end effector 2130 may be measured as the degree of inclination of the end effector 2130 relative to the preset position in a third direction Z, using data measured by the displacement sensors 220a, 220b, and 220c.

The data measured by the displacement sensors 220 may include values related to reception time or reception position.

If the reception time of the data measured by the displacement sensors 220 has a third specific value, it may be determined that the end effector 2130 is positioned at the preset position in the third direction Z. If the reception time of the data measured by the displacement sensors 220 does not have the third specific value, it may be determined that the end effector 2130 is not positioned at the preset position in the third direction Z.

For example, if the reception time of the data measured by the displacement sensors 220 is constant, it may indicate that the end effector 2130 was not present along the measurement path of the displacement sensors 220.

If the reception time of the data measured by the displacement sensors 220 is constant, it may be determined that there has been no interference from the end effector 2130. Conversely, if the reception time is not constant, it may be determined that there has been interference from the end effector 2130. The presence of interference from the end effector 2130 means that the end effector 2130 is positioned at the measurement position of the displacement sensors 220. Conversely, the absence of interference from the end effector 2130 means that the end effector 2130 is not positioned at the measurement position of the displacement sensors 220.

Alternatively, if the reception time of the data measured by the displacement sensors 220 is relatively long, it may indicate that there has been no interference from the end effector 2130. Conversely, if the reception time is relatively short, it may indicate that there has been interference from the end effector 2130.

For example, if the reception position of the data measured by the displacement sensors 220 is constant, it may be determined that there has been no interference from the end effector 2130. If the reception position of the data measured by the displacement sensors 220 is not constant, it may be determined that there has been interference from the end effector 2130. If the reception position of the data measured by the displacement sensors 220 deviates from the preset position, it may indicate that the substrate W or the end effector 2130 has not moved along a preset path.

Laser displacement sensors are used as the displacement sensors 220 because, compared to other types of sensors, they are relatively unaffected by surrounding noise, have lower measurement errors, and can provide more accurate results. Additionally, since laser displacement sensors are smaller than other types of sensors, they can be easily installed inside the carrier 5000, which has a limited internal space.

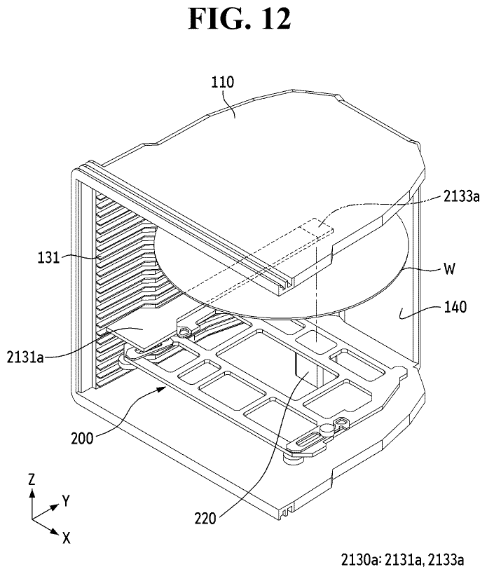

The installation position and number of displacement sensors 220 in the first plate 210 may vary depending on the shape or size of the end effector 2130. Additionally, the installation position or number of displacement sensors 220 may change depending on the type of information to be measured. Further details will be described later with reference to FIGS. 12 through 14.

The horizontal sensors 230a and 230b may be installed on the first plate 210. Specifically, the horizontal sensors 230a and 230b may be installed on the upper surface of the first plate 210. In some embodiments, the horizontal sensors 230a and 230b may be installed on the lower surface of the first plate 210. Alternatively, in some embodiments, the horizontal sensors 230a and 230b may be installed to overlap with the first through-holes H1 of the first plate 210.

One or more horizontal sensors 230a and 230b may be provided. The horizontal sensors 230a and 230b may measure the degree of inclination of the first plate 210 or the carrier 5000 from a horizontal perspective. For example, the horizontal sensors 230a and 230b may measure the degree of rotation of the first plate 210 or the carrier 5000 in a first direction X and a second direction Y.

The number and installation position of the horizontal sensors 230a and 230b are not limited to those illustrated. By measuring the horizontal alignment of the first plate 210 or the carrier 5000 through the horizontal sensors 230a and 230b, the reliability of the inspection device according to some embodiments of the present disclosure can be improved.

The first fixing pins 240 may be installed on the first plate 210. The first fixing pins 240 may be installed at the edges of the first plate 210. The first fixing pins 240 may connect the first plate 210 and the housing 100. By connecting the first plate 210 and the housing 100, the plate module 200 can be stably mounted in the housing 100.

Referring to FIGS. 6 and 8, the second plate module 300 may include a second plate 310, reflectors 320a, 320b, and 320c, and second fixing pins 330.

The carrier 5000 may include a second plate 310 parallel to the upper surface 110, the lower surface 120, and the first plate 210 of the housing 510. The second plate 310 may be positioned between the upper surface 110 of the housing 510 and the substrate W. However, the position of the second plate 310 is not limited thereto, and if the first plate module 200 is positioned between the upper surface 110 of the housing 100 and the substrate W, the second plate 310 may be positioned between the lower surface 120 of the housing 100 and the substrate W. That is, the second plate 310, the end effector 2130 that has entered the carrier 5000, and the first plate 210 may be sequentially arranged along the third direction Z.

In some embodiments, the second plate 310 may include second through-holes H2, which are holes passing through the second plate 310. The location, size, and number of second through-holes H2 may vary and are not limited to those illustrated. The formation of the second through-holes H2 may reduce the overall weight of the second plate module 300.

The reflectors 320a, 320b, and 320c may be installed on the second plate 310. In some embodiments, the reflectors 320a, 320b, and 320c may be installed on the lower side of the second plate 310. The reflectors 320a, 320b, and 320c may reflect signals emitted from the displacement sensors 220. For example, the reflectors 320a, 320b, and 320c may reflect light emitted from the displacement sensors 220. The reflectors 320a, 320b, and 320c may overlap with the displacement sensors 220 in the third direction Z. The reflectors 320a, 320b, and 320c may face the displacement sensors 220 in the third direction Z.

The inspection device according to some embodiments of the present disclosure may detect changes in measured values caused by displacement variations of the displacement sensors 220 or the first plate 210 through the reflectors 320a, 320b, and 320c. By detecting displacement variations of the displacement sensors 220 using the reflectors 320a, 320b, and 320c, the reliability of measurements obtained by the displacement sensors 220 can be improved.

The second fixing pins 330 may be installed on the second plate 310. The second fixing pins 330 may be installed at the edges of the second plate 310. The second fixing pins 330 may connect the second plate 310 and the housing 100. By connecting the second plate 310 and the housing 100, the second plate module 300 can be stably mounted to the housing 100. The second fixing pins 330 may have a similar shape to the first fixing pins 240.

Referring to FIGS. 6 and 9, the third plate module 400 may include a third plate 410, a connector board 420, a signal processing board 440, a battery 450, and a controller 430.

The carrier 5000 may include a third plate 410 mounted inside the housing 510. The third plate 410 includes a third fixing pin 460. The third plate 410 may be mounted on the substrate mounting rails 131 or may be positioned at the lower portion of the carrier 5000. The third plate 410 may be positioned between the lower surface 120 of the housing 510 and the first plate module 200. However, the position of the third plate 410 is not limited to that illustrated.

In some embodiments, the third plate 410 may include a third through-hole H3, which is a hole passing through the third plate 410. The location, size, and number of third through-holes H3 may vary and are not limited to those illustrated. As the third through-hole H3 is formed, the overall weight of the third plate module 400 can be reduced.

The signal processing board 440 may process signals received from the displacement sensors 220 and convert analog data into digital data. The signal processing board 440 may function as an interface that transmits the digital data to the controller 430.

In some embodiments, the signal processing board 440 may amplify signals collected from the displacement sensor 220 and remove electrical noise that may occur due to external environmental factors, thereby improving signal purity. In some embodiments, the signal processing board 440 may perform analog-to-digital conversion (ADC) to enable data processing. The data collected through the displacement sensors 220 may be processed through linearization, offset correction, and filtering, thereby enhancing data reliability and facilitating subsequent analysis and output on the display device 143.

The signal processing board 440 may be installed on the third plate 410, but is not limited thereto. The signal processing board 440 may be positioned inside the carrier 5000.

The connector board 420 may provide electrical connections between the components of the carrier 5000, and may efficiently distribute signals and power between the displacement sensors 220, the signal processing board 440, the controller 430, the display device 143, and the battery 450. The connector board 420 may provide physical connections between the components of the carrier 5000 and facilitate detachment and replacement of the individual components, thereby enhancing maintenance convenience for the carrier 5000.

The connector board 420 may integrate or distribute signals output from multiple displacement sensors 220a, 220b, and 220c as needed. Additionally, the connector board 420 may properly distribute power supplied from the battery 450 to the components of the carrier 5000. In some embodiments, the connector board 420 may include a protection circuit to prevent overcurrent, overvoltage, and short circuits, and may provide an interface for connection to an external device.

The connector board 420 may be installed on the third plate 410, but is not limited thereto. The connector board 420 may be positioned inside the carrier 5000.

The controller 430, which serves as the central processing unit of the inspection device according to some embodiments of the present disclosure, may comprehensively manage the data processing of the displacement sensors 220 and the output of the display device 143. The controller 430 may analyze the digital data collected from the signal processing board 440 and generate an inspection result based on the analysis. Additionally, the controller 430 may control the display device 143 to visually present the inspection result to a user. The controller 430 may also monitor the remaining power of the battery 450 and adjust the operating modes of the controller 430 and the display device 143 to minimize power consumption.

The controller 430 may transmit data to and receive data from an external system via a communication interface such as USB, Bluetooth, and Wi-Fi. The inspection device according to some embodiments of the present disclosure may process data collected from the displacement sensor 220 with high precision through the controller 430 and provide the result of the processing in real time to the user via the display device 143. The controller 430 may be installed on the third plate 410, but is not limited thereto. The controller 430 may be positioned inside the carrier 5000.

The battery 450 may enable the carrier 5000 to operate independently. The battery 450 may be charged externally via the charging connector 145 installed on the rear surface 140 of the housing 100. The battery 450 may be charged through the charging connector 145 and used permanently. The battery 450 may power the displacement sensors 220, the connector board 420, the signal processing board 440, the controller 430, and the display device 143 inside the inspection device according to some embodiments of the present disclosure.

As the third plate module 400 is included inside the inspection device according to some embodiments of the present disclosure, the inspection device according to some embodiments of the present disclosure can operate independently without requiring a wired connection to an external source. As a result, the inspection device according to some embodiments of the present disclosure can be transported independently to inspect a variety of equipment, providing a significant advantage.

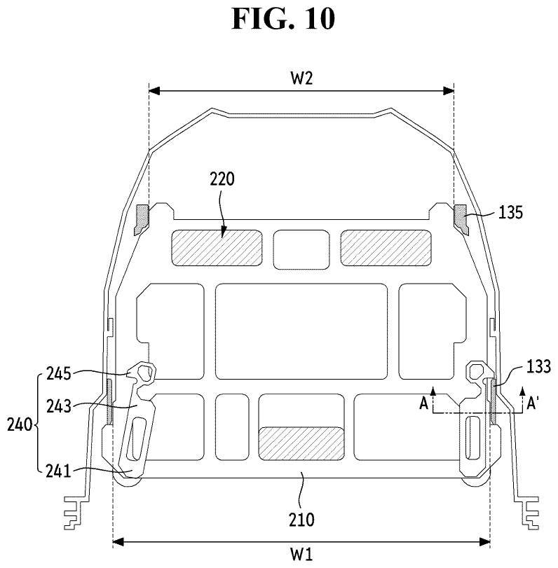

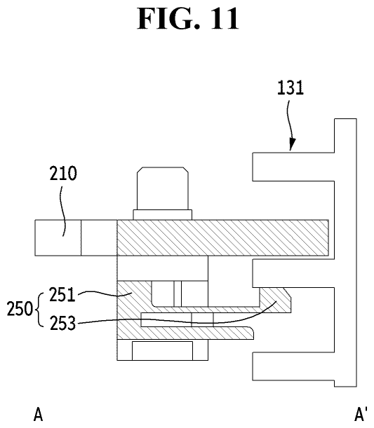

FIG. 10 is a cross-sectional view illustrating how the first plate module illustrated in FIG. 3 is fixed to the housing. FIG. 11 is a cross-sectional view taken along line A-A′ of FIG. 10.

Referring to FIG. 10, the first plate 210 may include a first end positioned near the entrance 150 of the housing 100 and a second end positioned near the rear surface 140 of the housing 100. The first end may have a first width W1, and the second end may have a second width W2. In some embodiments, the first width W1 may be greater than the second width W2. Similarly, the width of the entrance 150 of the housing 100 in the first direction X may be greater than the width of the rear surface 140 of the housing 100 in the first direction X. By having a shape where the first width W1 is greater than the second width W2, the first plate 210 may have a shape similar to that of the housing 100. By having a similar shape to the housing 100, the first plate 210 can be more securely fixed to the housing 100 and the substrate mounting rails 131.

Referring to FIG. 10, the first fixing pins 240 may each include a pin 241, an extension portion 243, and a latch portion 245. The first fixing pin 240 may be connected to the first plate 210 via the pin 241. The pin 241 may be fixed to the first plate 210, and the extension portion 243 and the latch portion 245 may be rotatable.

The latch portions 245 of the first fixing pins 240 may rotate to engage with first fixing mounts 133. The latch portions 245 may be in a partially protruding shape. The latch portions 245 may include curved protrusions directed toward the first fixing mounts 133. The latch portions 245 may correspond to the first fixing mounts 133. Parts of the latch portions 245 may be connected to the first fixing mounts 133 to fix the first plate 210 to the housing 100. A pair of first fixing pins 240 may be present on the first plate 210. A pair of first fixing mounts 133 may be positioned facing each other in the second direction Y.

The first fixing mounts 133 may be formed by portions of the side surfaces 130 of the housing 100 that protrude outward. The first fixing mounts 133 may be located between a plurality of substrate mounting rails 131. Alternatively, the first fixing mounts 133 of the housing 100 may be formed by portions of the substrate mounting rails 131 that protrude in the third direction Z. The first fixing mounts 133 may be positioned to correspond to the first fixing pins 240. The first fixing pins 240 of the first plate module 200 may be connected to the first fixing mounts 133 to fix the first plate 210 to the housing 100.

As the first fixing pins 240 are connected to the first fixing mounts 133, the first plate 210 and the first plate module 200 can be secured without moving in the second direction Y. As a result, the stability and reliability of the first plate 210 and the first plate module 200 can be improved.

Second fixing mounts 135 may be formed by portions of the side surfaces 130 of the housing 100 that protrude outward. The second fixing mounts 135 may be located between a plurality of substrate mounting rails 131. Alternatively, the second fixing mounts 135 of the housing 100 may be formed by portions of the substrate mounting rails 131 that protrude in the third direction Z. The second fixing mounts 135 may be positioned near the rear surface 140 of the housing 100. A pair of second fixing mounts 135 may be arranged to face each other in the first direction X.

The first end of the first plate 210, which is positioned near the entrance 150 of the housing 100, may be arranged to correspond to the first fixing mounts 133 of the housing 100. The distance between the first fixing mounts 133 in the first direction X may be equal to or greater than the first width W1.

Since the distance between the first fixing mounts 133 in the first direction X corresponds to the width of the first end of the first plate 210, the first plate 210 may be fixed in place without moving in the first direction X due to the first fixing mounts 133.

The second end of the first plate 210, which is positioned near the rear surface 140 of the housing 100, may be arranged to correspond to the second fixing mounts 135 of the housing 100. The distance between the second fixing mounts 135 in the first direction X may be equal to or greater than the second width W2.

Since the distance between the second fixing mounts 135 in the first direction X corresponds to the width of the second end of the first plate 210, the first plate 210 may be fixed in place without moving in the first direction X due to the second fixing mounts 135.

Referring to FIGS. 10 and 11, the first plate module 200 may further include preload structures 250. The preload structures 250 may be positioned at the edges of the first plate 210. The preload structures 250 may be shaped to enclose portions of the substrate mounting rails 131.

Specifically, each of the preload structures 250 may include a preload portion 251 in which a portion of the first plate 210 protrudes in the third direction Z. The preload portion 251 may include an elastic member. The elastic member may be, for example, a spring. The preload portion 251 may apply a preset preload to the substrate mounting rails 131 via the elastic member.

Each of the preload structures 250 may further include a support portion 253, which protrudes in the first direction X. The support portion 253 may be parallel to the first plate 210. The support portion 253 may be connected via the preload portion 251 and may support and fix the first plate 210 and the substrate mounting rails 131. By applying preload to the substrate mounting rails 131, the preload structures 250 allows the first plate 210 to be closely secured to the substrate mounting rails 131. Accordingly, the first plate module 200 can be stably positioned inside the housing 100.

FIG. 12 is a perspective view illustrating a first inspection process of the inspection device according to some embodiments of the present disclosure. For convenience, the second and third plate modules 300 and 400 are omitted in FIG. 12, but the present disclosure is not limited thereto.

Referring to FIG. 12, the first inspection process of the inspection device according to some embodiments of the present disclosure may involve inspecting the movement path of a first end effector 2130a. The first end effector 2130a may be, for example, in the form of a bar with a single hand. The first end effector 2130a may move the single hand in the second direction Y to transport a substrate W.

The first end effector 2130a may include a first robot arm 2131a and a first hand portion 2133a. The first robot arm 2131a may be connected to the rotary arm 2110. The first robot arm 2131a may extend in the second direction Y to form the first hand portion 2133a. The first hand portion 2133a may be in the form of a bar extending in the second direction Y from the first robot arm 2131a. The first hand portion 2133a may be a single hand. The first hand portion 2133a may transport a substrate W mounted on the substrate mounting rail 131.

In the first inspection process, one displacement sensor 220 may be installed in the first plate module 200 of the inspection device according to some embodiments of the present disclosure. The displacement sensor 220 may detect positional changes of the first end effector 2130a in the third direction Z. For example, the displacement sensor 220 may detect positional changes of the first end effector 2130a in the third direction Z when the first end effector 2130a enters or retracts from the carrier 5000.

In the first inspection process, the first hand portion 2133a of the first end effector 2130a may overlap with the displacement sensor 220 in the third direction Z. Specifically, when the first end effector 2130a enters the carrier 5000 to perform a get operation, the first hand portion 2133a may overlap with the displacement sensor 220 in the third direction Z. The displacement sensor 220 may be installed at a position on the first plate 210 where it overlaps with an end of the first hand portion 2133a in the third direction Z.

For example, when the first end effector 2130a enters the carrier 5000, light emitted from the light-emitting unit of the displacement sensor 220 may be reflected by the first hand portion 2133a of the first end effector 2130a. The light reflected by the first hand portion 2133a may then be received by the light-receiving unit of the displacement sensor 220. At this time, the displacement sensor 220 may determine the position of the first hand portion 2133a in the third direction Z based on the position of the received light. Specifically, if the position of the light received by the light-receiving unit of the displacement sensor 220 deviates from a preset position, the controller 430 may determine that the first end effector 2130a is operating abnormally. Conversely, if the position of the light received by the light-receiving unit of the displacement sensor 220 matches the preset position, the controller 430 may determine that the first end effector 2130a is operating normally.

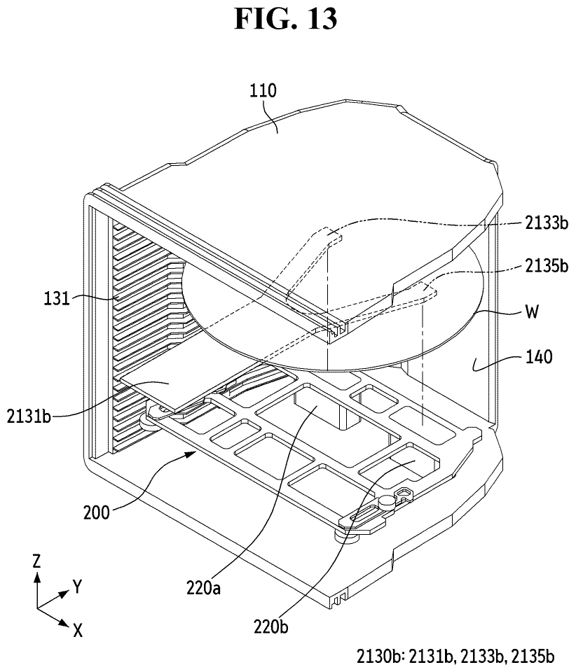

FIG. 13 is a perspective view illustrating a second inspection process of the inspection device according to some embodiments of the present disclosure. For convenience, the second plate module 300 and the third plate module 400 are omitted in FIG. 13, but the present disclosure is not limited thereto.

Referring to FIG. 13, the second inspection process of the inspection device according to some embodiments of the present disclosure may involve inspecting the movement path of a second end effector 2130b. The second end effector 2130b may, for example, have a dual-hand configuration. The second end effector 2130b may move the two hands in the second direction Y to transport a substrate W.

The second end effector 2130b may include a second robot arm 2131b, a second hand portion 2133b, and a third hand portion 2135b. The second robot arm 2131b may be connected to the rotary arm 2110. The second robot arm 2131b may extend in the second direction Y to form the second and third hand portions 2133b and 2135b. The second and third hand portions 2133b and 2135b may be spaced apart from each other in the first direction X. The second and third hand portions 2133b and 2135b may form a V-shape. The second and third hand portions 2133b and 2135b may transport a substrate W mounted on the substrate mounting rails 131.

In the second inspection process, the inspection device according to some embodiments of the present disclosure may include two displacement sensors 220a and 220b installed on the first plate module 200. The two displacement sensors 220a and 220b may detect positional changes of the second end effector 2130b in the third direction Z. For example, the displacement sensors 220a and 220b may detect positional changes of the second end effector 2130b in the third direction Z as it enters or retracts from the carrier 5000.

In the second inspection process, the second hand portion 2133b may overlap with one of the displacement sensors (e.g., 220a) in the third direction Z. One of the two displacement sensors (e.g., 220a) may be installed at a position on the second plate 310 where it overlaps with one end of the second hand portion 2133b in the third direction Z. Specifically, when the second end effector 2130b enters the carrier 5000 to perform a get operation, the second hand portion 2133b may overlap with one of the two displacement sensors (e.g., 220a) in the third direction Z.

In the second inspection process, the third hand portion 2135b may overlap with one of the displacement sensors (e.g., 220b) in the third direction Z. One of the two displacement sensors (e.g., 220b) may be installed at a position on the second plate 310 where it overlaps with one end of the third hand portion 2135b in the third direction Z. When the second end effector 2130b enters the carrier 5000 to perform a get operation, the third hand portion 2135b may overlap with one of the two displacement sensors (e.g., 220b) in the third direction Z.

During the second inspection process, the carrier 5000 may detect positional changes of the second end effector 2130b in the third direction Z based on data measured by the two displacement sensors 220a and 220b. Specifically, the two displacement sensors 220a and 220b may collect data while overlapping with the second and third hand portions 2133b and 2135b as the second end effector 2130b performs a get operation. The carrier 5000 may determine whether the second end effector 2130b is operating normally by analyzing measurement data obtained from both the displacement sensors 220a and 220b.

For example, when the second end effector 2130b enters the carrier 5000, light emitted from the light-emitting unit of one of the two displacement sensors (e.g., 220a) may be reflected by the second hand portion 2133b of the second end effector 2130b. The light reflected by the second hand portion 2133b may then be received by the light-receiving unit of one of the two displacement sensors (e.g., 220a). At this time, the position of the light received by the light-receiving unit of one of the two displacement sensors (e.g., 220a) may be used to determine the position of the second hand portion 2133b in the third direction Z.

For example, when the second end effector 2130b enters the carrier 5000, light emitted from the light-emitting unit of one of the two displacement sensors (e.g., 220b) may be reflected by the third hand portion 2135b of the second end effector 2130b. The light reflected by the third hand portion 2135b may then be received by the light-receiving unit of one of the two displacement sensors (e.g., 220b). At this time, the position of the light received by the light-receiving unit of one of the two displacement sensors (e.g., 220b) may be used to determine the position of the third hand portion 2135b in the third direction Z.

Specifically, if the position of a beam of light received by the light-receiving unit of one of the two displacement sensors (e.g., 220a) deviates from a preset position, the controller 430 may determine that the second end effector 2130b is operating abnormally. Alternatively, if the positions of beams of light respectively received by the light-receiving units of the two displacement sensors 220a and 220b are different, the controller 430 may determine that the second end effector 2130b is operating abnormally. Conversely, if the positions of the beams of light received by the light-receiving units of the two displacement sensors 220a and 220b match the preset position, the controller 430 may determine that the second end effector 2130b is operating normally.

Ideally, to perform a get operation or a put operation inside the carrier 5000, the end effector 2130 may move horizontally. However, in many cases, when the end effector 2130 performs a get operation or a put operation inside the carrier 5000, the hand portion(s) of the end effector 2130 may tilt in the third direction Z. Therefore, by adjusting the number of displacement sensors 220 to correspond to the number of hand portions of the end effector 2130, the accuracy of the inspection device can be improved. That is, by modifying the number of displacement sensors 220 according to the configuration of the end effector 2130, the reliability of the inspection device according to some embodiments of the present disclosure can be enhanced. However, the number and installation position of the displacement sensors 220 are not limited to those illustrated.

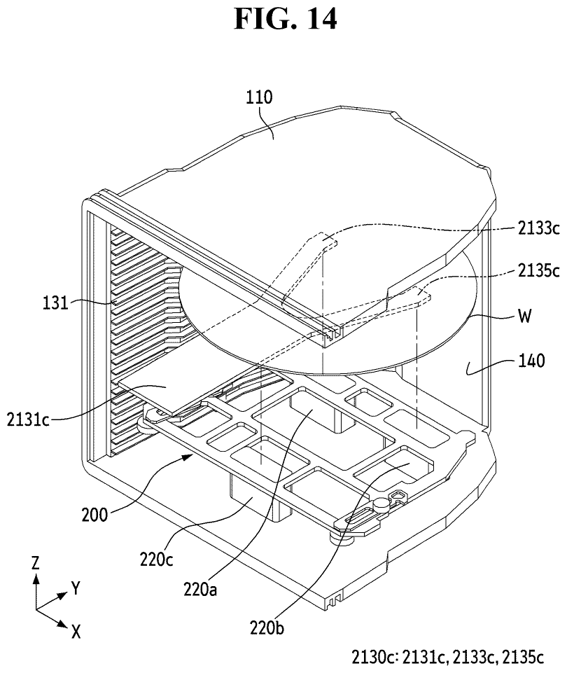

FIG. 14 is a perspective view illustrating a third inspection process of the inspection device according to some embodiments of the present disclosure. For convenience, the second and third plate modules 300 and 400 are omitted in FIG. 14, but the present disclosure is not limited thereto.

Referring to FIG. 14, the third inspection process of the inspection device according to some embodiments of the present disclosure may involve inspecting the movement path of a third end effector 2130c. The third end effector 2130c may, for example, have a dual-hand configuration. The third end effector 2130c may have a similar configuration to the second end effector 2130b. The third end effector 2130c may move the two hands in the second direction Y to transport a substrate W.

The third end effector 2130c may include a third robot arm 2131c, a fourth hand portion 2133c, and a fifth hand portion 2135c. The third robot arm 2131c may be connected to the rotary arm 2110. The third robot arm 2131c may extend in the second direction Y to form the fourth and fifth hand portions 2133c and 2135c. The fourth and fifth hand portions 2133c and 2135c may be spaced apart from each other in the first direction X. The fourth and fifth hand portions 2133c and 2135c may form a V-shape. The fourth and fifth hand portions 2133c and 2135c may transport a substrate W mounted on the substrate mounting rails 131.

In the third inspection process, the inspection device according to some embodiments of the present disclosure may include three displacement sensors 220a, 220b, and 220c installed on the first plate module 200. The three displacement sensors 220a, 220b, and 220c may detect the movement path or positional changes of the third end effector 2130c. For example, the three displacement sensors 220a, 220b, and 220c may detect the movement path of the third end effector 2130c as it enters or retracts from the carrier 5000.

In the third inspection process, the fourth hand portion 2133c may overlap with one of the displacement sensors (e.g., 220a) in the third direction Z. One of the three displacement sensors (e.g., 220a) may be installed at a position on the second plate 310 where it overlaps with one end of the fourth hand portion 2133c in the third direction Z. Specifically, when the third end effector 2130c enters the carrier 5000 to perform a get operation, the fourth hand portion 2133c may overlap with one of the three displacement sensors (e.g., 220a) in the third direction Z.

In the third inspection process, the fifth hand portion 2135c may overlap with one of the displacement sensors (e.g., 220b) in the third direction Z. One of the three displacement sensors (e.g., 220b) may be installed at a position on the second plate 310 where it overlaps with one end of the fifth hand portion 2135c in the third direction Z. Specifically, when the third end effector 2130c enters the carrier 5000 to perform a get operation, the fifth hand portion 2135c may overlap with one of the three displacement sensors (e.g., 220b) in the third direction Z.

In the third inspection process, the third robot arm 2131c may overlap with one of the displacement sensors (e.g., 220c) in the third direction Z. One of the three displacement sensors (e.g., 220c) may be installed at a position on the second plate 310 where it partially overlaps with the third robot arm 2131c in the third direction Z. Specifically, when the third end effector 2130c enters the carrier 5000 to perform a get operation, the third robot arm 2131c may overlap with one of the three displacement sensors (e.g., 220c) in the third direction Z.

During the third inspection process, the carrier 5000 may detect the movement path or positional changes of the third end effector 2130c based on data measured by the three displacement sensors 220a, 220b, and 220c. Specifically, the three displacement sensors 220a, 220b, and 220c may collect data while overlapping with the fourth hand portion 2133c, the fifth hand portion 2135c, and the third robot arm 2131c as the third end effector 2130c performs a get operation. The carrier 5000 may use measurement data obtained from the three displacement sensors 220a, 220b, and 220c to detect the movement path of the third end effector 2130c.

For example, when the third end effector 2130c enters the carrier 5000, light emitted from the light-emitting unit of one of the three displacement sensors (e.g., 220a) may be reflected by the fourth hand portion 2133c of the third end effector 2130c. The light reflected by the fourth hand portion 2133c may then be received by the light-receiving unit of one of the three displacement sensors (e.g., 220a). At this time, the position of the light received by the light-receiving unit of one of the three displacement sensors (e.g., 220a) may be used to determine the position of the fourth hand portion 2133c in the third direction Z.

For example, when the third end effector 2130c enters the carrier 5000, light emitted from the light-emitting unit of one of the three displacement sensors (e.g., 220b) may be reflected by the fifth hand portion 2135c of the third end effector 2130c. The light reflected by the fifth hand portion 2135c may then be received by the light-receiving unit of one of the three displacement sensors (e.g., 220b). At this time, the position of the light received by the light-receiving unit of one of the three displacement sensors (e.g., 220b) may be used to determine the position of the fifth hand portion 2135c in the third direction Z.

For example, when the third end effector 2130c enters the carrier 5000, light emitted from the light-emitting unit of one of the three displacement sensors (e.g., 220c) may be reflected by the third robot arm 2131c of the third end effector 2130c. The light reflected by the third robot arm 2131c may then be received by the light-receiving unit of one of the three displacement sensors (e.g., 220c). At this time, the position of the light received by the light-receiving unit of one of the three displacement sensors (e.g., 220c) may be used to determine the position of the third robot arm 2131c in the third direction Z.

Specifically, if the position of a beam of light received by the light-receiving unit of one of the three displacement sensors (e.g., 220a) deviates from a preset position, the controller 430 may determine that the third end effector 2130c is operating abnormally. Alternatively, if the positions of beams of light received by the three displacement sensors 220a, 220b, and 220c are different, the controller 430 may determine that the third end effector 2130c is operating abnormally. Conversely, if the positions of the beams of light received by the three displacement sensors 220a, 220b, and 220c match the preset position, the controller 430 may determine that the third end effector 2130c is operating normally.

Additionally, when more than three displacement sensors 220 are used, the position of any unmeasured part of the end effector 2130 may also be estimated using the measurement data from the displacement sensors 220. Specifically, the displacement sensors 220 may measure the positions of portions of the end effector 2130 in the third direction Z, and may also estimate the positions of portions of the end effector 2130 they do not measure in the third direction Z. Therefore, the installation positions of the displacement sensors 220 are not limited to those illustrated.

Moreover, when more than three displacement sensors 220 are used, the inspection device according to some embodiments of the present disclosure may determine not only the position of the end effector 2130 in the third direction Z but also the rotation of the end effector 2130 in the first direction X or the second direction Y.

According to some embodiments of the present disclosure, since the displacement sensors 220 are provided inside the carrier 5000 to detect the movement path of the end effector 2130, any improper movement of the end effector 2130 can be quickly detected during the get or put process of the substrate W, thereby preventing damage to the substrate W.

The displacement sensors 220 and the controller 430 can prevent the end effector 2130 from damaging the substrate W or generating contaminants due to abnormal movement, ensuring stability in the substrate handling process.

Additionally, since the displacement sensors 220 and the controller 430 for detecting the position of the end effector 2130 are installed inside the carrier 5000, the inspection device according to some embodiments of the present disclosure offers ease of installation and maintenance advantages.

In concluding the detailed description, those skilled in the art will appreciate that many variations and modifications may be made to the preferred embodiments without substantially departing from the principles of the present disclosure. Therefore, the disclosed preferred embodiments of the disclosure are used in a generic and descriptive sense only and not for purposes of limitation.

What is claimed is:

1. An inspection device comprising:
a housing having an entrance through which a robot enters and retracts in a first direction, and a substrate mounting rail on which a substrate is mounted;
a first plate module including a first plate mounted on the substrate mounting rail and a displacement sensor installed on the first plate;
a controller provided inside the housing and configured to analyze data measured by the displacement sensor;
a display device provided inside, on a surface of, or outside the housing and configured to display information received from the controller and the displacement sensor; and
a battery provided inside the housing and configured to supply power to the controller and the display device,
wherein when the displacement sensor and the robot overlap in a second direction intersecting the first direction, the displacement sensor measures a position of the robot in the second direction.

2. The inspection device according to claim 1,
wherein the displacement sensor includes a light-emitting unit and a light-receiving unit, and
wherein the light-receiving unit is positioned on a same plane as the light-emitting unit and is integrally formed with the light-emitting unit.

3. The inspection device according to claim 2, wherein
the light-emitting unit emits a signal in the second direction, and
the light-receiving unit measures a first position at which the signal, reflected from the robot, is received by the light-receiving unit.

4. The inspection device according to claim 3, wherein the controller determines that the position of the robot in the second direction is normal when the first position is the same as a preset position, and determines that the position of the robot in the second direction is abnormal when the first position is different from the preset position.

5. The inspection device according to claim 2, further comprising:
a second plate module including a second plate provided inside the housing and a reflector installed on the second plate and overlapping with the displacement sensor in the second direction,
wherein:
when the displacement sensor and the robot do not overlap in the second direction, the reflector reflects a signal emitted by the light-emitting unit of the displacement sensor, and
when the displacement sensor and the robot overlap in the second direction, the second plate module, the robot, and the first plate module are sequentially arranged along the second direction.

6. The inspection device according to claim 1, wherein
the displacement sensor comprises a first displacement sensor and a second displacement sensor, and
the first and second displacement sensors are installed on the first plate to be spaced apart from each other.

7. The inspection device according to claim 6, wherein
the displacement sensor further comprises a third displacement sensor, and
the third displacement sensor is installed on the first plate to be spaced apart from the first and second displacement sensors.

8. The inspection device according to claim 1, wherein when the displacement sensor and the robot overlap in the second direction, the displacement sensor and an end of the robot overlap in the second direction.

9. The inspection device according to claim 1, wherein
the first plate includes a first end positioned near the entrance and a second end positioned farther from the entrance,
the first end has a first width,
the second end has a second width, and
the first width is greater than the second width.

10. The inspection device according to claim 9, wherein
the substrate mounting rail further includes a pair of first protrusions and a pair of second protrusions facing each other in the second direction, the pairs of first protrusions and second protrusions being formed by portions of the substrate mounting rail that protrude in the second direction,
the pair of first protrusions correspond to the first end,
a width between the pair of first protrusions is equal to the first width,
the pair of second protrusions correspond to the second end, and
a width between the pair of second protrusions is equal to the second width.

11. The inspection device according to claim 1, wherein
the first plate module further includes a preload structure that includes a preload portion formed by a part of the first plate extending in the second direction and including an elastic body, and a support portion formed by the preload portion extending in a third direction intersecting the first and second directions, and
the preload structure fixes the first plate module to the substrate mounting rail.

12. The inspection device according to claim 1, wherein
the first plate module further includes a latch having one end fixed to the first plate to be rotatable, and
the substrate mounting rail further includes a protrusion formed by a portion of the substrate mounting rail protruding in the second direction to correspond to the latch.

13. An inspection device comprising:
a housing including an entrance through which a robot enters and retracts in a first direction and a substrate mounting rail on which a substrate is mounted;
a first plate module including a first plate mounted on the substrate mounting rail and a plurality of displacement sensors installed on the first plate;
a controller provided inside the housing and configured to analyze data measured by the plurality of displacement sensors;
a display device provided inside, on a surface of, or outside the housing and configured to display information received from the controller and the plurality of displacement sensors; and
a battery provided inside the housing and configured to supply power to the controller and the display device,
wherein when the plurality of displacement sensors and the robot overlap in a second direction intersecting the first direction, each of the plurality of displacement sensors measures a position of the robot in the second direction.

14. The inspection device according to claim 13, wherein
the plurality of displacement sensors include a first displacement sensor and a second displacement sensor,
the first and second displacement sensors are installed on the first plate to be spaced apart from each other, and
when the plurality of displacement sensors and the robot overlap in the second direction, the first displacement sensor and a first end of the robot overlap in the second direction, and the second displacement sensor and a second end of the robot overlap in the second direction.

15. The inspection device according to claim 14, wherein
the first displacement sensor includes a first light-emitting unit and a first light-receiving unit, the first light-receiving unit being positioned on a same plane as and integrally formed with the first light-emitting unit,
the second displacement sensor includes a second light-emitting unit and a second light-receiving unit, the second light-receiving unit being positioned on a same plane as and integrally formed with the second light-emitting unit,
the first light-emitting unit emits a first signal in the second direction,
the first light-receiving unit measures a first position at which the first signal, reflected from the first end of the robot, is received by the first light-receiving unit,
the second light-emitting unit emits a second signal in the second direction, and
the second light-receiving unit measures a second position at which the second signal, reflected from the second end of the robot, is received by the second light-receiving unit.

16. The inspection device according to claim 13, wherein
the plurality of displacement sensors include a first displacement sensor, a second displacement sensor, and a third displacement sensor,
the first, second, and third displacement sensors are installed on the first plate to be spaced apart from each other, and
when the plurality of displacement sensors and the robot overlap in the second direction, the first, second, and third displacement sensors overlap with the robot in the second direction.

17. The inspection device according to claim 16, wherein
the first displacement sensor includes a first light-emitting unit and a first light-receiving unit, the first light-receiving unit being positioned on a same plane as and integrally formed with the first light-emitting unit,
the second displacement sensor includes a second light-emitting unit and a second light-receiving unit, the second light-receiving unit being positioned on a same plane as and integrally formed with the second light-emitting unit,
the third displacement sensor includes a third light-emitting unit and a third light-receiving unit, the third light-receiving unit being positioned on a same plane as and integrally formed with the third light-emitting unit,
the first light-emitting unit emits a first signal in the second direction,
the first light-receiving unit measures a first position at which the first signal, reflected from the robot, is received by the first light-receiving unit,
the second light-emitting unit emits a second signal in the second direction,
the second light-receiving unit measures a second position at which the second signal, reflected from the robot, is received by the second light-receiving unit,
the third light-emitting unit emits a third signal in the second direction, and
the third light-receiving unit measures a third position at which the third signal, reflected from the robot, is received by the third light-receiving unit.

18. The inspection device according to claim 13, further comprising:
a second plate module including a second plate provided inside the housing and a plurality of reflectors installed on the second plate and overlapping with the plurality of displacement sensors in the second direction,
wherein, when the plurality of displacement sensors and the robot overlap in the second direction, the second plate module, the robot, and the first plate module are sequentially arranged along the second direction.

19. An inspection device comprising:
a housing including an entrance through which a robot enters and retracts in a first direction and a substrate mounting rail on which a substrate is mounted;
a first plate module including a first plate mounted on the substrate mounting rail, a displacement sensor installed on the first plate, a leveling sensor configured to measure whether the first plate is level, a preload structure configured to fix the first plate to the substrate mounting rail, and a latch having one end fixed to the first plate to be rotatable;
a second plate module including a second plate provided inside the housing and a reflector installed on the second plate and overlapping with the displacement sensor in a second direction intersecting the first direction;
a third plate module including a third plate provided inside the housing, a controller installed on the third plate and configured to analyze data measured by the displacement sensor, and a battery installed on the third plate and configured to supply power to the controller; and
a display device provided inside, on a surface of, or outside the housing and configured to display information received from the controller and the displacement sensor,
wherein:
the preload structure includes a preload portion formed by a part of the first plate extending in the second direction and including an elastic body, and a support portion formed by the preload portion extending in a third direction intersecting the first and second directions, and
when the displacement sensor and the robot overlap in the second direction, the displacement sensor measures a position of the robot in the second direction, and the second plate module, the robot, and the first plate module are sequentially arranged along the second direction.

20. The inspection device according to claim 19, wherein
the displacement sensor includes a first displacement sensor and a second displacement sensor, and
the first and second displacement sensors are installed on the first plate to be spaced apart from each other.
